(19) United States
(12) Patent Application Publication
(10) Pub. No.: US 2015/0176118 A1
(43) Pub. Date: Jun. 25, 2015

(54) WEB SUBSTRATE ROLL-FORMING APPARATUS AND WEB SUBSTRATE ROLL

(71) Applicant: KABUSHIKI KAISHA KOBE SEIKO SHO (Kobe Steel, Ltd.), Kobe-shi, Hyogo (JP)

(72) Inventors: Hiroshi Tamagaki, Takasago-shi (JP); Naoki Ohba, Takasago-shi (JP); Eiji Yoshida, Takasago-shi (JP)

(73) Assignee: KABUSHIKI KAISHA KOBE SEIKO SHO (Kobe Steel, Ltd.), Kobe-shi, Hyogo (JP)

(21) Appl. No.: 14/412,030

(22) PCT Filed: Jul. 19, 2013
(86) PCT No.: PCT/JP2013/004409

§ 371 Date: Dec. 30, 2014

(30) Foreign Application Priority Data
Aug. 2, 2012 (JP) 2012-172053

(51) Int. Cl. C23C 14/56; B65H 18/08; B65H 18/28

(52) U.S. Cl. CPC C23C 14/562; B65H 18/28; B65H 18/08; B65H 2301/35; B65H 2701/1315

(57) ABSTRACT

Provided is an apparatus capable of preventing the intrusion of particles into spaces in a web substrate roll. The apparatus forms web substrate rolls by continuously winding a long web substrate (21), on which edge tabs (14) have been installed, in a chamber (5) under vacuum or under reduced pressure, and is provided with: a winding section (4) for winding the web substrate (21) and overlaying the edge tabs (14); and a filler-supplying section for adding a filler (20) between portions of the web substrate (21) that are adjacent to each other in the radial direction and are between the two edge tabs (14) by supplying the filler (20) to the web substrate (21) that is being wound on the winding section (4).

### TECHNICAL FIELD

The present invention relates to an apparatus for forming a web substrate roll by winding a flexible web substrate that can be wound into a roll and has edge tabs installed in both ends under vacuum or reduced pressure, and also to a web substrate roll formed by winding such a web substrate.

### BACKGROUND ART

Thin film glasses (glass films) with good gas barrier performance and transparency, etc. have recently been used increasingly as a substrate material for display devices for displaying videos and the like. While the thickness of such glass films is commonly about 200 μm, very thin glass films with a thickness smaller than 200 μm, for example, of 30 to 150 μm are nowadays being developed.

Such a very thin glass film, which has flexibility because of its thinness, can be used as a web substrate and wound into a roll to be handled as a web substrate roll. In some web substrate rolls employing such a glass film, a protective sheet (protective film) is sandwiched between portions of a rolled glass film adjacent to each other in the radial direction to prevent the contact with each other and thereby being damaged.

Alternatively, a technique for winding a glass film into a roll without such a protective sheet, that is, a glass film that can be wound without using a protective sheet is also being developed.

Non-Patent Document 1, for example, discloses a glass film protection method in which a glass film having protective members attached, respectively, to both ends in the width direction thereof is carried and wound around a winding roller or the like so that the glass film can be protected without using a protective sheet. Specifically, in the glass film protection method, the protective members, called edge tabs, are attached to the both ends in the width direction of the glass film to thereby prevent the glass film from being damaged during carriage.

With reference to the drawings of Non-Patent Document 1, the thickness of each edge tab is about 50% of that of the glass film. For example, if the glass film has a thickness of about 200 μm, the edge tabs have a thickness of about 100 μm. In Non-Patent Document 1, since a bending strength estimate for a glass film with a thickness of 50 μm is disclosed, it is conceivable that the glass film has a thickness of about 50 to 200 μm, and therefore that the edge tabs have a thickness of about 25 to 100 μm.

With reference to the drawings of Non-Patent Document 1, the width of each edge tab is about 5% of that of the glass film substrate. For example, since a rolling process for general tests is performed at a width of about 200 to 300 mm, it is conceivable that the edge tabs have a width of about 10 to 15 mm.

On the other hand, Patent Document 1 discloses a glass ribbon including a glass substrate (glass film) and protective members attached to both ends in the width direction of the glass substrate. The protective members, which are similar to the edge tabs in the above-described Non-Patent Document 1, allow the glass film to be protected without using a protective film. It is also disclosed that the protective members have a thickness of about 50 to 100 μm.

The edge tabs disclosed in Patent Document 1 and the protective members disclosed in Non-Patent Document 1 have a thickness of about 25 to 100 μm and serve as spacers between portions of the glass film during winding to form a space (clearance or gap) between portions of the glass film. Thus forming a clearance between portions of the glass film can prevent the glass film from coming into contact with the roller during carriage and prevent portions of the glass film adjacent to each other from coming into contact with each other during winding. The edge tabs can thus avoid contact between portions of the glass film and therefore the resultant damage of the glass film. This technique is found to be useful also for a method of carrying a polymer film and/or a metal foil.

If such a web substrate roll (glass roll) formed by winding a glass film having edge tabs undergoes a process of, for example, film formation on the glass film under vacuum or reduced pressure, an undesirable event can occur when the apparatus in which the glass roll has been set in the atmosphere is pumped to vacuum and when the inside of the apparatus is opened to the atmosphere after the completion of the process.

First, when a web substrate roll formed by winding a glass film having edge tabs is placed in a chamber under the atmospheric pressure and the chamber is pumped in a hermetically sealed state, a difference may occur between the pressure inside the chamber and the pressure inside the web substrate roll. Specifically, inside the web substrate roll, air exists in a very thin clearance formed by the edge tabs between portions of the glass film, and when the chamber is pumped at a certain rate or higher, a difference occurs between the pumping rate inside the chamber and the pumping rate inside the web substrate roll, resulting in such a pressure difference as mentioned above. That is, since the dimension of the whorl clearance inside the web substrate roll is much smaller than the whole length of the web substrate roll, it takes a long time for the air inside the web substrate roll to flow out of the web substrate roll through pumping of the chamber. Accordingly, the pumping rate inside the web substrate roll is lower than the pumping rate inside the chamber, so that the pressure inside the web substrate roll is higher than the pressure inside the chamber. Such a pressure difference can deform the web substrate roll and damage the wound glass film.

Also when the web substrate roll is brought back to the atmospheric pressure after the completion of the surface treatment of the glass film under vacuum, a difference opposite to the case of pumping occurs between the pressure (atmospheric pressure) inside the chamber and the pressure inside the web substrate roll. When the inside of the chamber is brought from the vacuum back to the atmospheric pressure, it takes a relatively long time for the air inside the chamber to flow into the very thin clearance inside the web substrate roll, resulting in a pressure difference between the inside of the chamber and the inside of the web substrate roll. That is, the pressure recovery rate inside the web substrate roll is lower than the pressure recovery rate inside the chamber, so that the pressure inside the web substrate roll is lower than the pressure inside the chamber. Such a pressure difference can deform the web substrate roll in a crushed manner and damage the glass film wound around a winding roller or the like.

These problems can be solved by significantly reduced-rate and prolonged pumping and pressure recovery of the chamber. However, there is a problem during pressure recovery that cannot be solved even with prolongation. That is, during pressure recovery, particles such as dust existing inside the chamber may intrude into the web substrate roll, which problem cannot be prevented even with prolongation of the pressure recovery because fine particles can join the flow of the atmosphere during pressure recovery and intrude into the web substrate roll through the pressure difference to attach to the surface of the web substrate.

### CITATION LIST

### Patent Document

Patent Document 1: U.S. Patent Application Publication No. 2011/0023548A1

### Non-Patent Document

Non-Patent Document 1: Flexible Glass Substrates for roll-to-roll manufacturing, S. Garner et al., AIMCAL 2011, Abstract

### SUMMARY OF THE INVENTION

It is an object of the present invention to provide an apparatus for forming a web substrate roll by winding a web substrate having edge tabs installed thereon under vacuum or reduced pressure, the apparatus capable of preventing the intrusion of particles into a clearance in the web substrate roll during pressure recovery, and also to provide a web substrate roll.

The present invention provides a web substrate roll-forming apparatus for forming a web substrate roll by continuously winding a long web substrate having edge tabs installed, respectively, in both ends in the width direction thereof in a chamber under vacuum or reduced pressure, the apparatus including: a winding section for winding the web substrate with the edge tabs to overlay the edge tabs; and a filler-supplying section for supplying a filler onto the web substrate to be wound on the winding section to add the filler between portions of the web substrate adjacent to each other in the radial direction and between the edge tabs.

The present invention also provides a web substrate roll formed by winding a long web substrate having edge tabs installed, respectively, in both ends in the width direction thereof in a manner overlaying the edge tabs, the roll including a filler added into an in-roll clearance formed between portions of the wound web substrate adjacent to each other in the radial direction so as to prevent foreign matters from intruding into the in-roll clearance.

### BRIEF DESCRIPTION OF THE DRAWINGS

FIG. 1 is a schematic view of a web substrate carrying apparatus according to a first embodiment of the present invention.

FIG. 2 shows a glass film having edge tabs installed thereon.

FIG. 3 (a) is a cross-sectional side view of a web substrate roll formed in the web substrate carrying apparatus according to the first embodiment and FIG. 3 (b) is a cross-sectional view taken along the line IIIB-IIIB in FIG. 3 (a).

FIG. 4 is an enlarged cross-sectional view of an end of the web substrate roll.

FIG. 5 (a) is a cross-sectional front view of substantial parts of a web substrate roll-forming apparatus and a web substrate roll according to a second embodiment of the present invention and FIG. 5 (b) is a cross-sectional view taken along the line VB-VB in FIG. 5 (a).

FIG. 6 is a schematic view of a web substrate roll-forming apparatus according to a third embodiment of the present invention.

### MODES FOR CARRYING OUT THE INVENTION

Embodiments of the present invention will hereinafter be described with reference to the accompanying drawings. In the embodiments to be described hereinafter and the drawings, identical components are designated by the same symbols and the same names. The components having the same symbols and the same names will not, therefore, be described repeatedly.

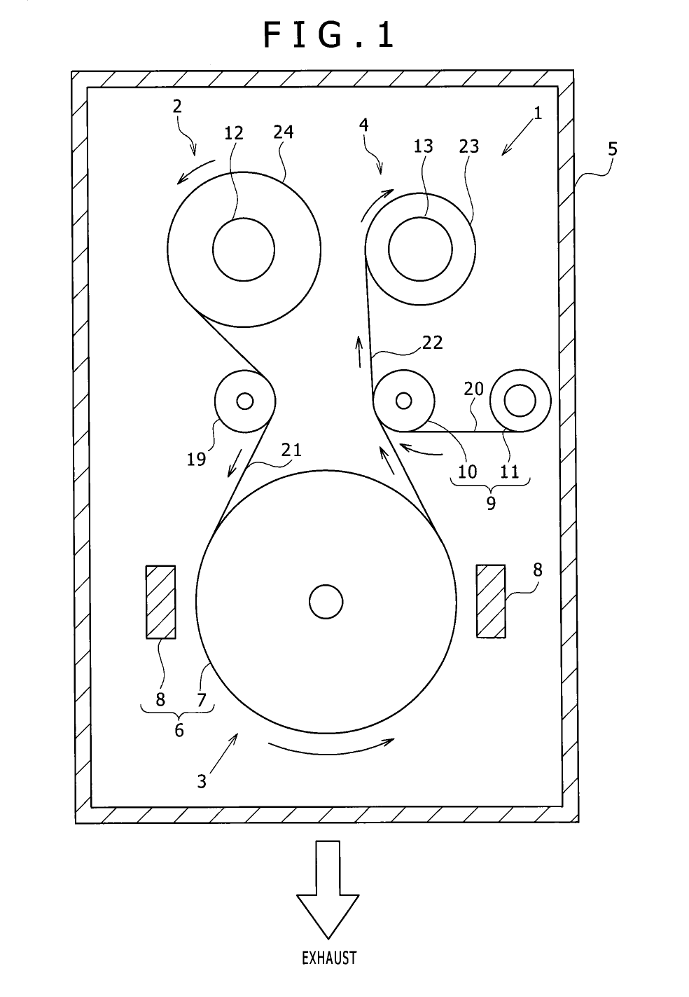

The vertical direction in facing the illustration of FIG. 1 corresponds to the vertical direction of a web substrate roll-forming apparatus according to the embodiments of the present invention. Similarly, the horizontal direction in facing the illustration corresponds to the horizontal direction of the web substrate carrying apparatus 1.

### First Embodiment

FIG. 1 shows a web substrate carrying apparatus 1 according to a first embodiment of the present invention. The web substrate carrying apparatus 1 is arranged to wind off a long thin film web substrate 21 from a web substrate roll 24 of the web substrate 21 wound in a roll, perform surface treatment such as sputtering or vapor deposition on the wound-off web substrate 21, and then wind the surface-treated web substrate 21 to form a web substrate roll 23. That is, the web substrate carrying apparatus 1 is arranged to carry the web substrate 21 in a so-called roll-to-roll system and includes a web substrate roll-forming apparatus for forming the web substrate roll 23.

The web substrate 21 is arranged similarly to the thin film glass disclosed in Non-Patent Document 1 that is described in Background Art and is formed in a very thin sheet having a length of 100 m or more, a width of about 1 m, and a thickness of about 50 to 200 μm, for example. The web substrate 21 is composed of, for example, thin film glass (glass film), polymer film, metal foil, or paper. The polymer film is molded of polymer such as PET (polyethylene terephthalate) or PEN (polyethylene naphthalate). The web substrate 21, which has flexibility because of its thinness, can be wound into a roll to be handled as the web substrate roll 24. In this embodiment, the web substrate 21 exemplarily employs a long thin film glass film and will be described as glass film 21 in the following description.

Referring to FIG. 1, the web substrate carrying apparatus 1 according to this embodiment includes a wind-off section 2 in which the glass film 21 is wound off from the web substrate roll 24, a film forming section 3 in which surface treatment is performed and a film is formed on the wound-off glass film 21, a winding section 4 in which the surface-treated glass film 21 is wound again into a web substrate roll 23, and a filler-supplying section 9, in which the winding section 4 and the filler-supplying section 9 constitute the web substrate roll-forming apparatus for forming the web substrate roll 23.

The wind-off section 2 has a rotatable wind-off core (winding core) 12. The wind-off core 12 is a cylindrical or columnar roller having an axial length greater than the width of the glass film 21. The glass film 21 with edge tabs to be described hereinafter in detail installed thereon is wound around the wind-off core 12 together with the edge tabs and to be wound off with the rotation of the wind-off core 12.

The film forming section 3 includes a film forming apparatus 6 for performing film formation on the glass film 21 as a kind of surface treatment such as sputtering, vapor deposition, or CVD. The film forming apparatus 6 includes a film forming roll 7 formed in a cylindrical or columnar shape and a vaporization source 8, in which the film forming roll 7 serves for the carriage of the glass film 21 and, during the carriage, the glass film 21 undergoes surface treatment. The film forming apparatus 6 will hereinafter be described in detail.

The winding section 4 has a winding core 13 and an actuator for rotationally driving the winding core 13. The winding core 13 is a cylindrical or columnar roller similar to the wind-off core 12 that constitutes the wind-off section 2. The actuator is arranged to rotationally drive the winding core 13 to wind, around the winding core 13, a multi-layer film 22 in which the glass film 21 surface-treated through the film forming apparatus 6 and a filler film 20 to be described hereinafter are layered. As will be described hereinafter in detail, the filler film 20 is a polymer solid member and formed in a long sheet.

As shown in FIG. 1, the thus arranged web substrate carrying apparatus 1 is housed in a vacuum chamber 5. The vacuum chamber 5 can be pumped to vacuum. The vacuum chamber 5 is formed in a hollow enclosure and kept airtight. Below the vacuum chamber 5 is provided a vacuum pump with which the vacuum chamber 5 can be pumped to a vacuum or reduced pressure state.

Next will be described the glass film 21 and the web substrate roll 24 formed by winding the glass film 21.

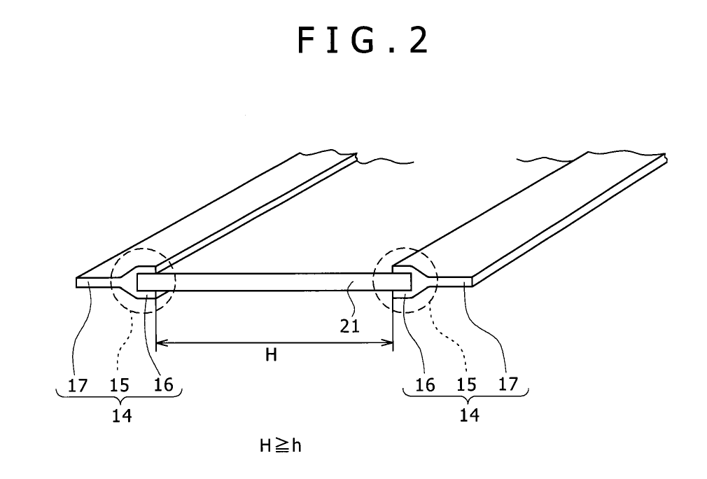

As shown in FIG. 2, the glass film 21 has edge tabs 14 installed thereon as protective members. The edge tabs 14 extend in the longitudinal direction of the thin glass film 21 and are installed, respectively, at both ends in the width direction of the glass film 21. Each edge tab 14 is a long tape-like member formed of, for example, a flexible polymer material and has a length approximately equal to that of the both ends in the width direction along the longitudinal direction of the glass film 21. The edge tabs 14 can be wound on the winding core 13 (roller) together with the glass film 21.

The arrangement of the edge tabs 14 will hereinafter be described in detail. It is noted that the vertical direction in facing the illustration of FIG. 2 corresponds to the vertical direction of the edge tabs 14. Similarly, the horizontal direction in facing the illustration corresponds to the horizontal direction of the edge tabs 14. It is also noted that for the sake of clear description, the illustration of FIG. 2 is enlarged in the vertical direction compared to the horizontal direction.

As shown in FIG. 2, when the edge tabs 14 and the glass film 21 with the edge tabs 14 installed thereon are cut perpendicularly to the longitudinal direction of the edge tabs 14, a section appears in which the edge tabs 14 are installed, respectively, in the both ends of the glass film 21. In the section (cross-section), focusing on the right edge tab 14 for the description of the arrangement thereof, the edge tab 14 has a support portion 15 for supporting one of the both ends along the longitudinal direction of the glass film 21 and a protrusion 17 protruding from the support portion 15. The edge tab 14 has a (lateral) width of, for example, about 10 to 20 mm, though not limited thereto.

The support portion 15 has a pair of spacer portions 16, which spacer portions 16 are formed in an arm to vertically hold therebetween a right end of the glass film 21 so as to come into contact with the upper and lower surfaces in the end. The thickness, that is, the vertical dimension of the spacer portions 16 is definitely set such that the glass film 21 can be wound flexibly into a roll, while portions of the glass film wound in a roll adjacent to each other in the radial direction can be prevented from coming into contact with each other. For example, if the glass film 21 has a thickness of about 50 to 200 μm, the thickness of the spacer portions 16 is preferably set within the range from about 25 to 100 μm. The thus formed two spacer portions 16 come into close contact with the upper and lower surfaces and the side surface in the right end of the glass film 21 to cover the right end of the glass film 21. The two spacer portions 16 are also coupled to each other on the outside of the glass film 21 in the width direction, that is, in the lateral direction.

The protrusion 17 is formed in a manner protruding opposite to the opening formed in the support portion 15. As shown in FIG. 2, the protrusion 17 protrudes rightward from the support portion 15 so as to extend in the width direction of the glass film 21. The cross-section of the edge tab 14 thus includes the support portion 15 in the form in which the inner end, that is, the end closer to the glass film 21 is branched vertically to form an opening, which support portion 15 supports the right end of the glass film 21.

The edge tab 14, which has such a cross-sectional shape as shown in FIG. 2, is formed by bonding long thin polymer tapes to the upper and lower surfaces of the glass film 21 to sandwich the end in the width direction of the glass film 21 along the longitudinal direction of the glass film 21. For example, a long polymer tape is bonded by about a half of the width thereof to the lower surface in the end of the glass film 21 along the longitudinal direction of the glass film 21. Subsequently, another long polymer tape is bonded by about a half of the width thereof to the upper surface in the end of the glass film 21 also along the longitudinal direction of the glass film 21. The other halves of the two long polymer tapes, which are not bonded to the glass film 21, are bonded to each other on the outside of the glass film 21. Thus, the support portion 15 is formed in which the two tapes sandwich, by about a half of the width thereof, the upper and lower surfaces in the end of the glass film, and the protrusion 17 is formed in which the other halves of the two tapes are integrated. The edge tab 14 is thus formed by integrating multiple members such as two tapes. The support portion 15 and the protrusion 17 of the edge tab 14 may be formed integrally using a single member.

It is noted that the arrangement of the left edge tab 14 shown in the cross-sectional view of FIG. 2 is the same as that of the above-described right edge tab 14 and hence will not be described.

When the glass film 21 with the edge tabs 14 installed in the left and right ends is wound into a web substrate roll 24 as mentioned above, the edge tabs 14 are overlaid in a whorl. In more detail, the spacer portions 16 of the support portion 15 of each edge tab 14 are overlaid on each other, whereby a space (clearance or gap) having a dimension equivalent to the thickness of the overlaid spacer portions 16 is formed between portions of the glass film 21 adjacent to each other in the radial direction. The thus formed clearance prevents portions of the glass film 21 adjacent to each other in the radial direction from coming into contact with each other and, accordingly, prevents the glass film 21 and therefore the web substrate roll from being damaged due to the contact.

The edge tabs 14 are not limited to such long ones as described heretofore, but may have a dimension smaller than the length of the left and right ends of the glass film 21. For example, the edge tabs 14 may be slightly shorter than half the total length of the left and right ends of the glass film 21 and, in each of the left and right ends, two such edge tabs 14 may be installed in line in the longitudinal direction of the glass film 21. Alternatively, multiple shorter edge tabs 14 may be installed in each of the left and right ends in a manner spaced from each other in the longitudinal direction of the left and right ends of the glass film 21. Even the use of such shorter edge tabs 14 could promise the same operational advantage as the case of using long edge tabs 14 because when the glass film 21 is wound, the edge tabs 14 and therefore the spacer portions 16 of the support portion 15 are overlaid, whereby a clearance having a dimension equivalent to the thickness of the overlaid spacer portions 16 is formed between portions of the glass film 21 adjacent to each other in the radial direction. That is, the clearance prevents portions of the glass film 21 adjacent to each other in the radial direction from coming into contact with each other and, accordingly, prevents the glass film 21 and therefore the web substrate roll from being damaged.

However, when the glass film 21 is wound in the vacuum chamber 5 and thereby a web substrate roll arranged similarly to the web substrate roll 24 with a clearance thus formed therein by the edge tabs 14 is formed and when the vacuum chamber 5 undergoes pressure recovery with the web substrate roll remaining housed in the vacuum chamber 5, there may arise a problem of intrusion of particles and the like into the clearance between portions of the glass film 21 due to the flow of air during the pressure recovery (hereinafter referred to also as foreign matter intrusion or contaminant incorporation in some cases). This is the case as described in Background Art.

On the other hand, the web substrate roll 23 formed by the web substrate roll-forming apparatus that is included in the web substrate carrying apparatus 1 according to this embodiment is characterized by having the filler film 20 for protection of the glass film 21 and therefore the web substrate roll 23 to prevent the intrusion of particles and the like in that the filler film 20 is added in the clearance formed by the edge tabs 14 between portions of the glass film 21, that is, interposed between portions of the glass film 21 adjacent to each other in the radial direction.

The filler film 20 according to this embodiment is a polymer solid member and formed in an elongated sheet. The length of the filler film 20 is approximately the same as that of the glass film 21 (100 m or less, for example). The width of the filler film 20 is slightly smaller than that of the glass film 21.

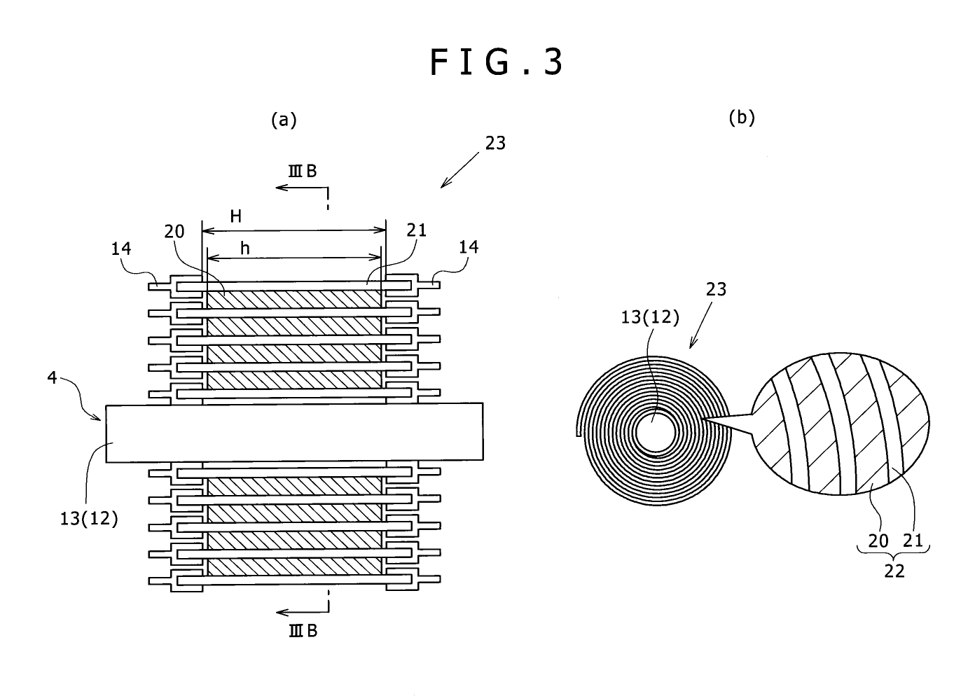

As shown in FIG. 3, the width h of the filler film 20 is equal to or smaller than the distance H between the edge tabs, a width within which the filler film 20 can be fitted and layered between the pair of edge tabs 14 installed in the left and right ends of the glass film 21 without overlapping the pair of edge tabs 14 (H≧h). However, if the width h of the filler film 20 is significantly smaller than H, a large clearance remains between the edge tabs 14, resulting in a reduction in the deterrent effect on the intrusion of particles and the like. Hence, the clearance between one end of the filler film 20 and the corresponding edge tab 14 has a width of smaller than 2.5 mm, and more preferably of smaller than 1 mm. That is, the relationship between the width h of the filler film and the distance H between the edge tabs 14 preferably meets the condition that H-h is smaller than 5 mm, and more preferably smaller than 2 mm.

The thickness of the filler film 20 is equal to the sum of the thickness of the (overlaid) spacer portions 16 of each edge tab 14 bonded to the upper and lower surfaces of the glass film, that is, the sum of the amount of projection of one of the spacer portions 16 from one surface of the filler film 20, which is a web substrate, and the amount of projection of the other spacer portion 16 from the other surface, or greater than the thickness of the overlaid spacer portions. For example, if the edge tabs 14 have a spacer portion with a thickness of 50 μm, the thickness of the filler film 20 is 100 μm or more. FIG. 3 shows the case where the thickness of the filler film 20 is greater than the sum of the thickness of the spacer portions 16.

The filler film 20, which is to be wound with being layered on the glass film 21, preferably has high flexibility and composed of a material that can withstand external shocks. For example, a polymeric material (polymer film) such as polyethylene, polypropylene, or polyvinyl chloride is preferable. Alternatively, soft metal foil or paper may be employed. The filler film 20 preferably has light adhesion on its surface. This is for the reason that even in case of particles attaching to the glass film, the particles adhere to the filler film, and thus the glass film can subsequently be wound off with no extraneous matter thereon.

By winding the glass film 21 having the edge tabs 14 installed thereon with the filler film 20 being layered thereon, the web substrate roll 23 is formed to include the edge tabs 14, the glass film 21 with the edge tabs 14 installed thereon, and the filler film 20, an example of a filler layered alternately on the glass film 21. That is, in the web substrate roll 23, the filler film 20 is interposed between portions of the wound glass film 21 adjacent to each other in the radial direction.

In a view of the web substrate roll 23 in the direction along the center axis thereof, the glass film 21 is wound in a whorl as shown in FIG. 3 (b), which is a cross-sectional view taken along the line IIIB-IIIB in FIG. 3 (a). In more detail, when the winding core 13 that is included in the winding section 4 shown in FIG. 3 (a) rotates, the glass film 21 with the filler film 20 layered thereon is wound together with the filler film 20. That is, the glass film 21 is wound around the winding core 13 in such a manner that the filler film 20 and the glass film 21 are layered alternately from the inner periphery toward the outer periphery.

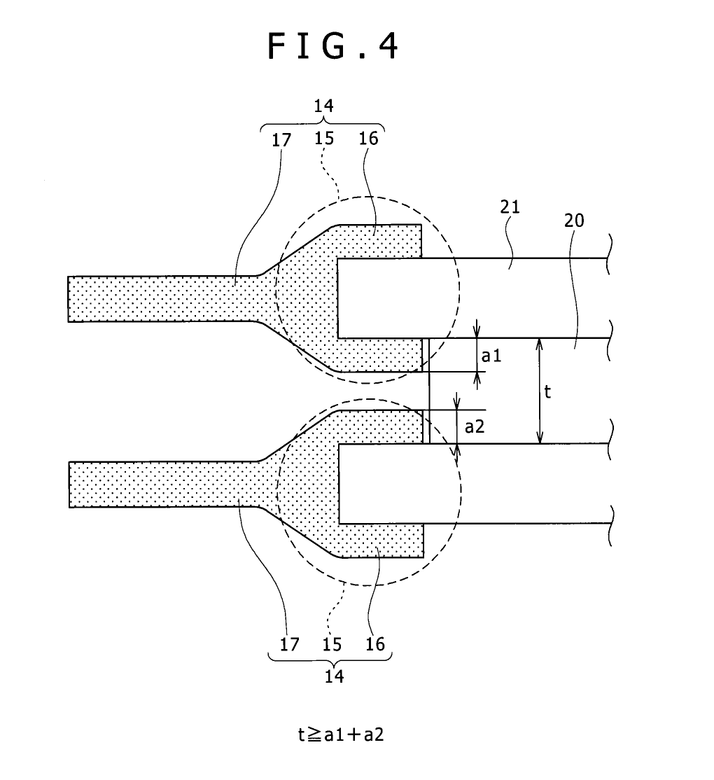

FIG. 4 is an enlarged view of a portion of the web substrate roll 23 shown in FIG. 3 where the edge tab 14 is installed. As shown in FIG. 4, the thickness t of the filler film 20 is greater than the sum (a1+a2) of the thickness a1 of one spacer portion 16 of the upper edge tab 14 and the thickness a2 of one spacer portion 16 of the lower edge tab 14 (t>a1+a2). This causes the edge tabs 14 adjacent to each other in the radial direction to be separated and a clearance to be formed between the edge tabs 14.

Alternatively, the thickness t of the filler film 20 may be equal to the sum of the thicknesses a1 and a2 of the upper and lower spacer portions 16 (t=a1+a2). In this case, the filler film 20 is added inside the web substrate roll 23 with no clearance.

Since the in-roll clearance between portions of the glass film 21 inside the web substrate roll 23 is thus filled with the filler film 20, which is a solid member constituting a filler, spaces containing air hardly exist inside the web substrate roll 23. That is, the web substrate roll 23 according to this embodiment has a dense structure in which spaces hardly exist into which air containing particles can flow during pressure recovery from the vacuum or reduced pressure state, whereby it is possible to prevent foreign matters such as particles and/or contaminants from flowing into the roll with the atmosphere during the pressure recovery. In a strict sense, if the width of the filler film 20 is slightly smaller than the spacing between the edge tabs 14, the surface of the glass film 21 is exposed, between the edge tabs 14 and the filler film 20, to a small space to be contaminated inevitably, which cannot, however, lead to a substantial problem because the portions of the glass film 21 just proximal to the edge tabs 14 are originally difficult to form a healthy film thereon.

Further, since the clearance between portions of the glass film 21 inside the web substrate roll 23 is filled with the filler film 20, which is a solid member constituting a filler, there is an additional advantage that even when the pressure outside the web substrate roll 23 may increase rapidly due to a pressure recovery operation, it is possible to prevent the web substrate roll from being damaged by the inside-outside pressure difference. It is therefore possible to increase the pressure recovery rate inside the chamber.

A method of carrying the glass film 21 and a method of forming the web substrate roll 23 using the web substrate carrying apparatus 1 will hereinafter be described specifically. It is noted that processes preceding the carriage of a glass film 21, such as providing and placing a web substrate roll 24 in the web substrate carrying apparatus 1, will not be described.

As shown in FIG. 1, the wind-off section 2 having the rotatable wind-off core 12 is arranged in an upper left part of the vacuum chamber 5, in which wind-off section 2 a glass film 21 with such edge tabs 14 as mentioned above installed thereon is wound around the wind-off core 12 to form a pretreatment web substrate roll 24. With the rotation of the wind-off core 12, the glass film 21 is wound off from the web substrate roll 24 and carried to the film forming section 3.

In the film forming section 3, the carried glass film 21 is applied onto the outer peripheral surface of the film forming roll 7 to undergo surface treatment. The film forming section 3 according to this embodiment includes the film forming apparatus 6 provided at a position below the center of the vacuum chamber 5. As shown in FIG. 1, the film forming apparatus 6 includes a sputtering vaporization source 8, for example, in addition to the film forming roll 7 for film formation by sputtering on the surface of the glass film 21. The sputtering vaporization source 8 is arranged at a position opposed to the glass film 21 carried on the film forming roll 7, for example two such sources at two positions in FIG. 1. The sputtering vaporization sources 8 are each equipped with a target including a component to be deposited on the surface of the glass film 21, in which a component vaporized by magnetron discharge is guided and deposited on the surface of the glass film 21, as is well known.

After thus surface-treated in the film forming section 3, the glass film 21 is carried to the filler film-supplying section 9. As shown in FIG. 1, the filler film-supplying section 9 is arranged upper right to the film forming roll 7 and layers the glass film 21 carried from the film forming roll 7 onto the filler film 20 to form a multi-layer film 22. The multi-layer film 22 is then carried to the winding section 4.

The winding section 4 is arranged in an upper right part of the vacuum chamber 5 in FIG. 1. The winding section 4 has the rotatable winding core 13 and the actuator for rotationally driving the winding core 13 as mentioned above, and the actuator rotates the winding core 13 to wind therearound the multi-layer film 22 and the edge tabs 14 installed on the glass film 21. The winding section 4 thus winds the carried multi-layer film 22 around the winding core 13 to form a web substrate roll 23 including the edge tabs 14 in cooperation with the filler film-supplying section 9 to be described hereinafter.

As shown in FIG. 3 (b), which is a cross-sectional view taken along the line IIIB-IIIB in FIG. 3 (a), inside the web substrate roll 23 including the multi-layer film 22 and the edge tabs 14 wound in the winding section 4, in-roll clearances formed between portions of the glass film 21 adjacent to each other in the radial direction are filled with the filler film 20. As a result, particles and the like are prevented from attaching to the surface of the glass film 21.

The filler film-supplying section 9, which corresponds to the filler-supplying section according to the present invention, will next be described in detail.

As shown in FIG. 1, the filler film-supplying section 9 according to this embodiment is arranged between the winding section 4 and the film forming roll 7 and has a multi-layering roller 10 and a filler film supply roll 11. The multi-layering roller 10 is formed in a cylindrical or columnar shape and arranged to layer the glass film 21 carried from the film forming roll 7 and the filler film 20 supplied from the filler film supply roll 11. The multi-layering roller 10 is arranged closer to the center of the vacuum chamber 5 with respect to the right end of the film forming roll 7, that is, closer to the rotation axis of the film forming roll 7 in the horizontal direction of the vacuum chamber 5 shown in FIG. 1. The filler film supply roll 11, in which the filler film 20 is wound around a winding core, rotationally supply the filler film 20 to the multi-layering roller 10. The filler film supply roll 11 is arranged right to the multi-layering roller 10 with predetermined spacing therebetween in the horizontal direction of the vacuum chamber 5 shown in FIG. 1.

The filler film-supplying section 9 thus supplies the filler film 20 onto the glass film 21 so that the glass film 21 and the filler film 20 are layered, and the filler film 20 and the glass film 21 are carried as the multi-layer film 22 to the winding section 4 to be formed as the web substrate roll 23.

In this embodiment, the web substrate roll 24 not including the filler film 20 is provided and placed in the wind-off section 2, but a roll including the filler film 20, like the web substrate roll 23, may be provided and placed in the wind-off section 2. In this case, it is necessary to separate the filler film 20 from the glass film 21 before supplying the glass film 21 to the film forming roll 7. The separation of the filler film 20 can be effected by, for example, providing a filler film removing section between the wind-off section 2 and the film forming roll 7.

The filler film removing section can include, for example, a separating roller substituted for and provided at the guide roller 19 arranged between the wind-off section 2 and the film forming roll 7 as shown in FIG. 1, and a filler film removing roller arranged downstream the separating roller. Like the multi-layering roller 10, the separating roller is formed in, for example, a columnar or cylindrical shape and, before the film forming section 3, separates the multi-layer film 22 wound off from the wind-off section 2 into the glass film 21 and the filler film 20. The separated filler film 20 is removed in a manner wound around the filler film removing roller. The glass film 21 is thus separated from the filler film 20 and carried to the film forming section 3. In more detail, the multi-layer film 22 carried from the wind-off section 2 is applied onto the separating roller with the filler film 20 in contact with the separating roller, and the filler film 20 is pulled by the filler film removing roller, while the glass film 21 is pulled by the film forming roll 7, whereby the glass film 21 and the filler film 20 can be separated. The glass film 21 is then carried to the film forming roll 7 to undergo surface treatment, while the filler film 20 is wound on the filler film removing roller.

As described heretofore, in the web substrate carrying apparatus 1, the glass film 21 with the edge tabs 14 installed thereon undergoes surface treatment, on which the filler film 20 thicker than the edge tabs 14 is subsequently layered, and the thus formed multi-layer film 22 is wound on the winding section 4 together with the edge tabs 14. This results in a formation of the web substrate roll 23 in which the glass film 21 can be prevented from being contaminated by particles during pressure recovery of the chamber 5.

### Second Embodiment

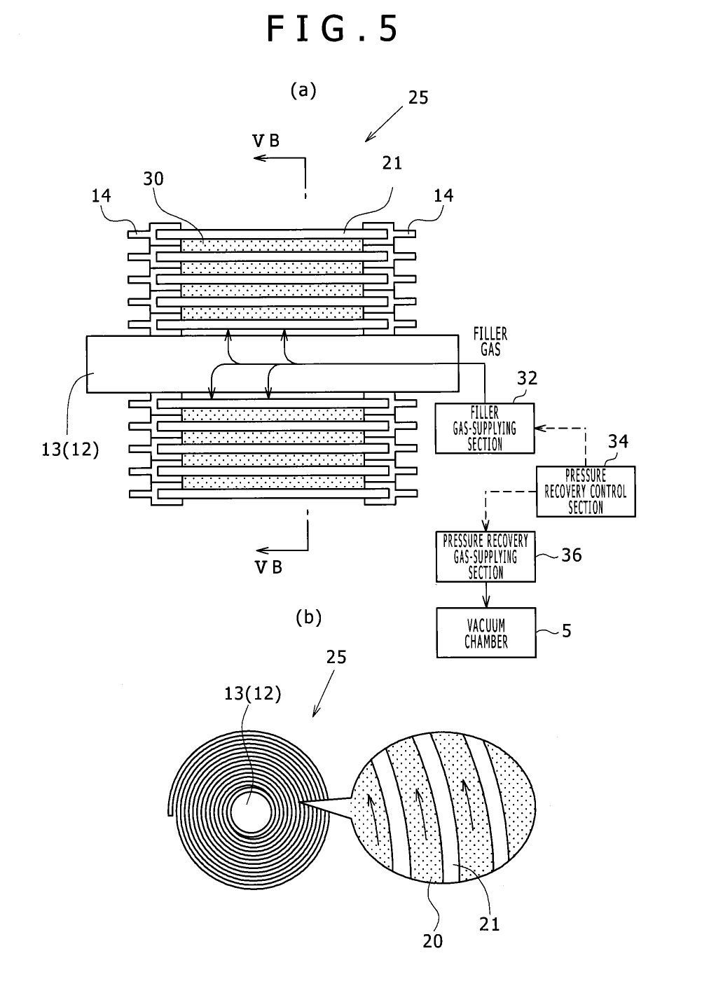

Next will be described a web substrate roll-forming apparatus and a chamber according to a second embodiment of the present invention with reference to FIG. 5.

The basic configuration of a web substrate carrying apparatus including the web substrate roll-forming apparatus and the chamber according to the second embodiment is equivalent to that of the web substrate carrying apparatus 1 and the chamber 5 according to the first embodiment, except that the configuration of the winding section 4 and the filler-supplying section included in the web substrate roll-forming apparatus is different from that in the first embodiment. Further, the web substrate roll-forming apparatus according to the second embodiment has a pressure recovery control section for controlling the pressure recovery rate and the like during pressure recovery of the chamber. In addition, the arrangement of a web substrate roll 25 formed in this embodiment is also different from the arrangement of the web substrate roll 23 formed in the first embodiment. First will be described the arrangement of the web substrate roll 25 according to this embodiment.

FIGS. 5 (a) and 5 (b) are cross-sectional views of the web substrate roll 25. The web substrate roll 25 is equivalent to the web substrate roll 23 according to the first embodiment in that a glass film 21 as an example of a web substrate and edge tabs 14 installed in the left and right ends of the glass film 21 are included, but different in that not the filler film 20 but gas is added as a filler into in-roll clearances formed inside the web substrate roll 25.

In the web substrate roll 25, the edge tabs 14 are overlaid in a whorl with the winding of the glass film 21, as is the case in the first embodiment. Specifically, portions of each edge tab 14 adjacent to each other in the radial direction of the web substrate roll 25 are overlaid through spacer portions 16 of a support portion 15 and, by the thickness of the overlaid support portions 15, a clearance is formed between portions of the glass film 21 adjacent to each other in the radial direction. In this second embodiment, cleaned filler gas 30, a kind of fluid (air, nitrogen, or argon, for example) is added as a filler into the thus formed clearance.

Next will be described the configuration of the web substrate roll-forming apparatus according to this second embodiment. In this embodiment, since the filler gas 30 is used as a filler, the web substrate roll-forming apparatus includes a filler gas-supplying section 32 for supplying the filler gas 30 onto the wound glass film 21, as a substitute for the filler film-supplying section 9 according to the first embodiment, and a pressure recovery control section 34.

Also in this second embodiment, the winding section 4 has a winding core 13. However, the winding core 13 is a hollow cylindrical roller with the interior extending straight in the axial direction thereof. Further, multiple slit-like or hole-like opening portions in communication with the hollow interior are formed in the outer peripheral surface of the winding core 13. The filler gas-supplying section 32 is connected to the hollow interior via an appropriate joint to feed the filler gas 30 through the hollow interior and further the opening portions in communication with the interior into in-roll clearances between portions of the glass film 21 wound around the winding core 13. The filler gas 30 is thus added into the in-roll clearances to constitute the web substrate roll 25 together with the glass film 21 and the edge tabs 14 installed on the glass film 21.

The pressure recovery control section 34 is arranged inside or outside the vacuum chamber 5 and arranged to, during pressure recovery of the vacuum chamber 5, control the amount of supply per unit time of pressure recovery gas to be supplied from a pressure recovery gas-supplying section 36 into the vacuum chamber 5 for the pressure recovery and the amount of supply per unit time by which the filler gas-supplying section 32 supplies the filler gas 30 through the winding core 13 into the in-roll clearances between portions of the glass film 21 in the web substrate roll 25 to thereby maintain the pressure inside the in-roll clearances between portions of the glass film 21 in the web substrate roll 25, that is, the pressure of the filler gas 30 equal to or higher than the pressure inside the vacuum chamber 5. This control can prevent the flow of gas (atmosphere) from the vacuum chamber 5 into the web substrate roll 25. This second embodiment is thus characterized by the arrangement of the winding core 13, the wind-off core 12, and the pressure recovery control section 34 and the arrangement for adding the filler gas 30 into the clearances inside the web substrate roll 25 in which the edge tabs 14 are installed.

A process of pressure recovery of the vacuum chamber 5 will be described below, focusing on the case where the glass film 21 is wound on the winding section 4.

First, in the vacuum chamber 5 in a vacuum state, the surface-treated glass film 21 with the edge tabs 14 installed thereon is wound around the winding core 13 that includes the opening portions, and thus the web substrate roll 25 including the edge tabs 14 is formed. The edge tabs 14 are overlaid in the radial direction with the winding of the glass film 21, whereby a clearance equivalent to the thickness of the overlaid spacer portions 16 of the edge tabs 14 is formed between portions of the glass film 21, particularly between portions of the glass film 21 adjacent to each other in the radial direction.

Next, in order to take out the web substrate roll 25, the pressure recovery gas-supplying section 36 feeds pressure recovery gas such as external air into the vacuum chamber 5 to bring the inside of the vacuum chamber 5 back to the atmospheric pressure. Here, if the clearances in the web substrate roll 25, that is, the in-roll clearances remain unfilled, the pressure inside the web substrate roll 25 would be lower than the pressure inside the vacuum chamber 5 under the pressure recovery because the pressure recovery rate of the clearances inside the web substrate roll 25 would be lower than the pressure recovery rate inside the vacuum chamber 5. The pressure difference could cause air inside the vacuum chamber 5 to be introduced into the web substrate roll 25 having the edge tabs 14 and thereby particles contained in the air inside the vacuum chamber 5 to intrude into the web substrate roll 25.

Hence, in this second embodiment, the in-roll clearances inside the web substrate roll 25 are filled with the cleaned filler gas 30 (containing no particle) that is supplied through the winding core 13 into the in-roll clearances, the intrusion of particles into which is thus prevented. Specifically, the filler gas 30 is fed by the filler gas-supplying section 32 into the hollow interior of the winding core 13 and then supplied through the slit-like opening portions provided in the winding core 13 into the clearances inside the web substrate roll 25, that is, following the clearances formed in a whorl. The in-roll clearances inside the web substrate roll 25 are thus filled with the cleaned filler gas 30.

Upon this, the pressure recovery control section 34 controls the amount of supply of gas (atmosphere) to be fed into the vacuum chamber 5 depending on the pressure recovery rate inside the web substrate roll 25. According to the control of the pressure recovery control section, the winding section 4 supplies the filler gas 30 through the winding core 13 into the clearances inside the web substrate roll 25. This control prevents pressure recovery gas (atmosphere, for example) for pressure recovery of the vacuum chamber 5 from flowing into the web substrate roll 25 and thereby particles contained in the pressure recovery gas from intruding into the web substrate roll 25 and attaching to the surface of the glass film 21. FIG. 5 (b) shows the thus pressure-recovered web substrate roll 25.

The filler gas 30 used in this second embodiment is cleaned fluid excluding fine particles and the like. In a method of cleaning the gas, for example, the filler gas 30 before introduction into the web substrate roll 25 is allowed passage through a cleaning filter or the like to remove fine particles and the like contained in the gas.

During the pressure recovery of the vacuum chamber 5, the filler gas 30 can be supplied approximately into the clearances inside the web substrate roll 25 to prevent contaminants such as particles from intruding into the web substrate roll 25.

### Third Embodiment

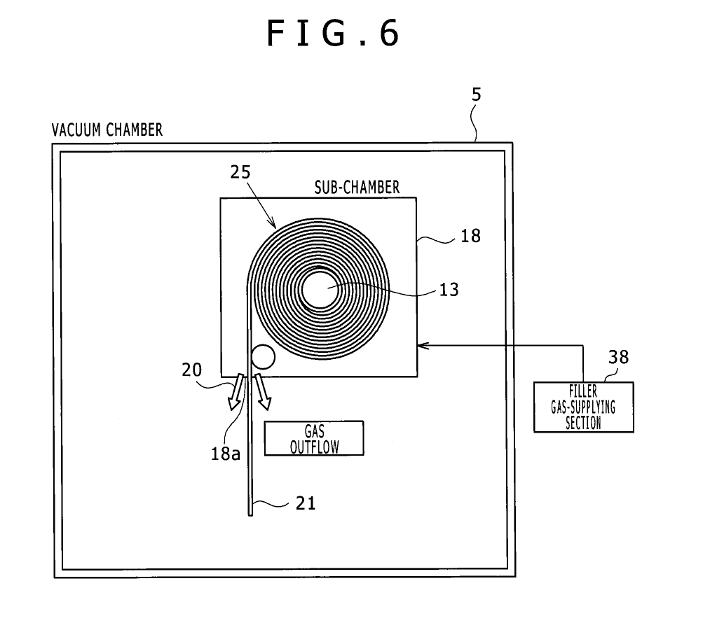

Next will be described a web substrate roll-forming apparatus according to a third embodiment of the present invention with reference to FIG. 6.

In addition to the winding section 4 for winding a glass film 21 to form a web substrate roll 25, the apparatus shown in FIG. 6 includes a sub-chamber 18 housed in the vacuum chamber 5 and a filler gas-supplying section 38 for supplying filler gas 30 into the sub-chamber 18.

The sub-chamber 18 encloses and houses the winding section 4 therein. FIG. 6 is a side view showing the web substrate roll 25 enclosed in the sub-chamber 18. Unlike the winding core 13 used in the second embodiment, the winding core 13 according to this third embodiment is not limited to having hollow interior to supply the filler gas 30. The winding core 13 according to this third embodiment may be a columnar solid roller, as is the case in the first embodiment. Also, the web substrate roll 25 according to this third embodiment includes edge tabs 14, as is the case with the web substrate roll 25 according to the second embodiment.

The sub-chamber 18 is formed in a hollow enclosure capable of isolating the interior space of the sub-chamber 18 substantially from the interior space of the vacuum chamber 5 external thereto. The filler gas-supplying section 38 is arranged to supply the cleaned filler gas 30 into the sub-chamber 18 during pressure recovery of the vacuum chamber 5 to thereby supply the filler gas 30 into the clearances inside the web substrate roll 25 and, at the same time, maintain the pressure inside the sub-chamber 18 higher than inside the vacuum chamber 5 to prevent the inflow of the atmosphere containing particles from the vacuum chamber 5.

The sub-chamber 18 has a slit 18a as an opening that allows passage therethrough of the glass film 21 included in the web substrate roll 25 that is housed inside the sub-chamber 18. The slit 18a has a shape that can reduce the intercommunication of the atmosphere between the interior of the sub-chamber 18 and the interior space of the vacuum chamber 5 external thereto while allowing passage of the glass film 21.

A process of pressure recovery of the vacuum chamber 5 will be described below, focusing on the sub-chamber 18 enclosing the winding section 4.

In order to take out the web substrate roll 25 formed in the winding section 4, pressure recovery gas (atmosphere, for example) is supplied into the vacuum chamber 5 to bring the inside of the vacuum chamber 5 back to the atmospheric pressure. At the same time, the sub-chamber 18 is supplied with the filler gas 30, cleaned gas containing no particle. Upon this, one or both of the amount of supply of the cleaned gas into the sub-chamber 18 and the amount of introduction of the atmosphere into the vacuum chamber 5 is controlled such that the pressure inside the sub-chamber 18 is constantly higher than the pressure inside the vacuum chamber 5 external thereto. The sub-chamber 18 is in communication with the vacuum chamber 5 through the slit 18a, which is a narrow opening that can reduce the intercommunication of the atmosphere while allowing passage of the glass film 21, and thus prevents the atmosphere containing particles in the vacuum chamber 5 from flowing into the sub-chamber 18. In addition, since the pressure inside the sub-chamber 18 is maintained higher than the pressure inside the vacuum chamber 5, a flow of the cleaned gas is formed from inside the sub-chamber 18 through the slit 18a into the vacuum chamber 5 external to the sub-chamber 18, and the flow further reliably prevents the atmosphere from flowing into the sub-chamber 18.

As described heretofore, the atmosphere in the vacuum chamber, that is, the pressure recovery gas containing particles cannot flow into the sub-chamber 18, but only the cleaned gas, that is, the filler gas 30 is supplied. The cleaned gas is supplied into the clearances inside the web substrate roll 25 and brings the pressure inside the clearances back to the atmospheric pressure eventually over time. Specifically, the cleaned gas introduced into the sub-chamber 18 inflows as the filler gas 30 following the whorl in-roll clearances formed inside the web substrate roll 25. The filler gas 30 thus added into the clearances inside the web substrate roll 25 can prevent contaminants from intruding into the web substrate roll 25 when the web substrate roll 25 is subsequently taken out of the sub-chamber 18.

In the region thus enclosed in the sub-chamber 18, the atmosphere can be maintained much cleaner than the atmosphere in the vacuum chamber 5 because unlike the vacuum chamber 5, there is no film forming source or the like that can generate particles in the sub-chamber 18, and additionally the sub-chamber 18 is a narrow closed region in which only the web substrate roll 25 exists substantially. The region can prevent the intrusion of particles when the filler gas 30 is supplied into the web substrate roll 25. When the web substrate roll 25 is taken out, since the web substrate roll 25 is filled with the filler gas 30, cleaned gas, there is no room inside the web substrate roll 25 for particles to intrude.

The sub-chamber 18 may be removable from the vacuum chamber 5 with the web substrate roll 25 being held therein, that is, with the web substrate roll 25 being combined therewith, which is also a preferred embodiment. In this embodiment, the web substrate roll 25 can be stored or transported while remaining housed inside the sub-chamber 18 filled with the cleaned gas.

It is noted that the above-disclosed embodiments should be considered illustrative and non-limiting in all aspects. Particularly, in the above-disclosed embodiments, items not explicitly disclosed, such as operating conditions and measuring conditions, various parameters, dimension, weight, and volume of the components, etc. cannot depart from the scope of ordinary implementation by those skilled in the art and employ values that can easily occur to those of ordinary skill in the art.

As described heretofore, in accordance with the present invention, there are provided an apparatus for forming a web substrate roll by winding a web substrate having edge tabs installed thereon under vacuum or reduced pressure, the apparatus capable of preventing the intrusion of particles into a clearance in the web substrate roll during pressure recovery, and also a web substrate roll.

The present invention provides a web substrate roll-forming apparatus for forming a web substrate roll by continuously winding a long web substrate having edge tabs installed, respectively, in both ends in the width direction thereof in a chamber under vacuum or reduced pressure, the apparatus including: a winding section for winding the web substrate with the edge tabs to overlay the edge tabs; and a filler-supplying section for supplying a filler onto the web substrate to be wound on the winding section to add the filler between portions of the web substrate adjacent to each other in the radial direction and between the edge tabs.

The present invention also provides a web substrate roll formed by winding a long web substrate having edge tabs installed, respectively, in both ends in the width direction thereof in a manner overlaying the edge tabs, the roll including a filler added into an in-roll clearance formed between portions of the wound web substrate adjacent to each other in the radial direction so as to prevent foreign matters from intruding into the in-roll clearance.

In the web substrate roll-forming apparatus and the web substrate roll formed by the apparatus, the filler is added in the in-roll clearance formed between portions of the web substrate wound inside the web substrate roll adjacent to each other in the radial direction, whereby it is possible to prevent foreign matters such as particles from intruding into the in-roll clearance during pressure recovery from the vacuum or reduced pressure state.

In the web substrate roll-forming apparatus, the filler-supplying section may be arranged to supply as the filler an elongated solid member formed in a sheet, the solid member having a width fittable between the pair of edge tabs installed in the both ends in the width direction of the web substrate and a thickness equal to or greater than the sum of the amount of projection of the edge tabs from one surface of the web substrate and the amount of projection of the edge tabs from the other surface or may be arranged to supply cleaned filler gas as the filler. That is, the filler included in the web substrate roll that the present invention provides may be the solid member or the filler gas.

If the filler is the solid member, the solid member preferably has a width fittable between the pair of edge tabs installed in the both ends in the width direction of the web substrate and a thickness equal to or greater than the sum of the amount of projection of the edge tabs from one surface of the web substrate and the amount of projection of the edge tabs from the other surface or may be arranged to supply cleaned filler gas as the filler. The solid member having such a thickness can reliably fill up the in-roll clearance in the thickness direction.

On the other hand, if the filler is the filler gas, the web substrate roll-forming apparatus preferably further includes a pressure recovery control section for controlling the amount of supply per unit time of the gas by the filler-supplying section and the amount of supply per unit time of pressure recovery gas to be supplied into the chamber for pressure recovery such that the pressure of the filler gas to be added into the web substrate roll is maintained equal to or higher than the pressure inside the chamber during the pressure recovery. The pressure recovery control section can control the amount of supply per unit time of the filler gas to be equal to or larger than the amount of supply per unit time of the pressure recovery gas to thereby prevent the pressure recovery gas from flowing into the web substrate roll.

It is also preferred that the filler-supplying section is provided in the chamber and includes a sub-chamber housing the winding section therein and a filler gas-supplying section for supplying the filler gas into the sub-chamber such that the pressure inside the sub-chamber is higher than the pressure inside the chamber. Thus supplying the filler gas into the sub-chamber such that the pressure inside the sub-chamber is higher than the pressure inside the chamber allows to prevent the gas in the chamber from flowing into the sub-chamber.

1. A web substrate roll-forming apparatus for forming a web substrate roll by continuously winding a long web substrate having edge tabs installed, respectively, in both ends in the width direction thereof in a chamber under vacuum or reduced pressure, the apparatus comprising:
a winding section for winding the web substrate with the edge tabs to overlay the edge tabs; and
a filler-supplying section for supplying a filler onto the web substrate to be wound on the winding section to add the filler between portions of the web substrate adjacent to each other in the radial direction and between the edge tabs.

2. The web substrate roll-forming apparatus according to claim 1, wherein the filler-supplying section is arranged to supply as the filler an elongated solid member formed in a sheet, the solid member having a width fittable between the pair of edge tabs installed in the both ends in the width direction of the web substrate and a thickness equal to or greater than the sum of the amount of projection of the edge tabs from one surface of the web substrate and the amount of projection of the edge tabs from the other surface.

3. The web substrate roll-forming apparatus according to claim 1, wherein the filler-supplying section is arranged to supply cleaned filler gas as the filler.

4. The web substrate roll-forming apparatus according to claim 3, further comprising a pressure recovery control section for controlling the amount of supply of the filler gas by the filler-supplying section and the amount of supply of pressure recovery gas to be supplied into the chamber for pressure recovery such that the pressure of the filler gas to be added into the web substrate roll is maintained equal to or higher than the pressure inside the chamber during the pressure recovery.

5. The web substrate roll-forming apparatus according to claim 3, wherein the filler-supplying section is provided in the chamber and includes a sub-chamber housing the winding section therein and a filler gas-supplying section for supplying the filler gas into the sub-chamber such that the pressure inside the sub-chamber is higher than the pressure inside the chamber.

6. A web substrate roll formed by winding a long web substrate having edge tabs installed, respectively, in both ends in the width direction thereof in a manner overlaying the edge tabs, the roll comprising a filler added into an in-roll clearance formed between portions of the wound web substrate adjacent to each other in the radial direction so as to prevent foreign matters from intruding into the in-roll clearance.

7. The web substrate roll according to claim 6, wherein the filler is an elongated solid member formed in a sheet, the solid member having a width fittable between the pair of edge tabs installed in the both ends in the width direction of the web substrate and a thickness equal to or greater than the sum of the amount of projection of the edge tabs from one surface of the web substrate and the amount of projection of the edge tabs from the other surface.

8. The web substrate roll according to claim 6, wherein the filler is cleaned gas to be added into the in-roll clearance.
